(19) United States
(12) Patent Application Publication
(10) Pub. No.: US 2026/0353625 A1
(43) Pub. Date: Nov. 5, 2026

(54) MEMORY DEVICE

(71) Applicants: TSMC NANJING COMPANY LIMITED, Nanjing (CN); TAIWAN SEMICONDUCTOR MANUFACTURING COMPANY, LTD., Hsinchu (TW)

(72) Inventors: Luping KONG, Nanjing City (CN); Jun-Cheng LIU, Nanjing City (CN); Chien-Yu HUANG, Taoyuan City (TW); Ching-Wei WU, Nantou County (TW)

(73) Assignees: TSMC NANJING COMPANY LIMITED, Nanjing (CN); TAIWAN SEMICONDUCTOR MANUFACTURING COMPANY, LTD., Hsinchu (TW)

(21) Appl. No.: 19/202,194

(22) Filed: May 8, 2025

(30) Foreign Application Priority Data
Apr. 17, 2025 (CN) 202520734683.7

(51) Int. Cl. H10B 10/00; G11C 11/419

(52) U.S. Cl. CPC H10B 10/12; G11C 11/419

(57) ABSTRACT

The memory device includes a first read data line coupled to a first memory segment; a second read data line coupled to a second memory segment, and including a first portion passing through the first memory segment and a second portion passing the second memory segment; and a first strap cell interposed between the first memory segment and the second memory segment. The first portion of the second read data line terminates and coupled to the second portion of the second read data line at the first strap cell.

### CROSS REFERENCE

The present application claims priority to China Application Serial Number 202520734683.7 filed on Apr. 17, 2025, which is herein incorporated by reference in its entirety.

### BACKGROUND

In addition to cycle time, access time is another crucial performance metric for high-performance computing (HPC) applications. SRAM, widely employed in system-on-chip (SoC) designs, utilizes keepers to mitigate disturbance effects. However, increasing the number of bitcells per bitline (BL) necessitates stronger keepers, which in turn can negatively impact the speed of BL discharge.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory cell in accordance with various embodiments of the present disclosure.

FIG. 2 is a schematic diagram of a memory device including the memory cell corresponding to FIG. 1, in accordance with other embodiments of the present disclosure.

FIG. 3A is a layout diagram of part of the memory device in FIG. 2, in accordance with other embodiments of the present disclosure.

FIG. 3B is a cross-sectional diagram of part of the memory device along line AA′ in FIG. 3A, in accordance with other embodiments of the present disclosure.

FIG. 4A is a layout diagram of part of the memory device in FIG. 2, in accordance with other embodiments of the present disclosure.

FIG. 4B is a cross-sectional diagram of part of the memory device along line BB′ in FIG. 4A, in accordance with other embodiments of the present disclosure.

FIG. 4C is a cross-sectional diagram of part of the memory device along line CC′ in FIG. 4A, in accordance with other embodiments of the present disclosure.

FIG. 5 is a schematic circuit diagram of a read circuit, in accordance with other embodiments of the present disclosure.

FIG. 6 is a schematic waveform diagram of signals in the memory device, in accordance with other embodiments of the present disclosure.

FIG. 7 is a schematic diagram of a memory device, in accordance with other embodiments of the present disclosure.

FIG. 8 is a schematic diagram of a memory device, in accordance with other embodiments of the present disclosure.

FIG. 9 is a schematic diagram of a memory device, in accordance with other embodiments of the present disclosure.

FIG. 10A is a layout diagram of part of the memory device in FIG. 9, in accordance with other embodiments of the present disclosure.

FIG. 10B is a cross-sectional diagram of part of the memory device along line DD′ in FIG. 10A, in accordance with other embodiments of the present disclosure.

FIG. 11A is a layout diagram of part of the memory device in FIG. 9, in accordance with other embodiments of the present disclosure.

FIG. 11B is a cross-sectional diagram of part of the memory device along line EE′ in FIG. 11A, in accordance with other embodiments of the present disclosure.

FIG. 12 is a schematic circuit diagram of a read circuit and signal generating circuits, in accordance with other embodiments of the present disclosure.

FIG. 13 is a schematic waveform diagram of signals in the memory device, in accordance with other embodiments of the present disclosure.

FIG. 14 is a schematic diagram of a memory device, in accordance with other embodiments of the present disclosure.

FIG. 15 is a flowchart of a method for operating a memory device to perform a read operation, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

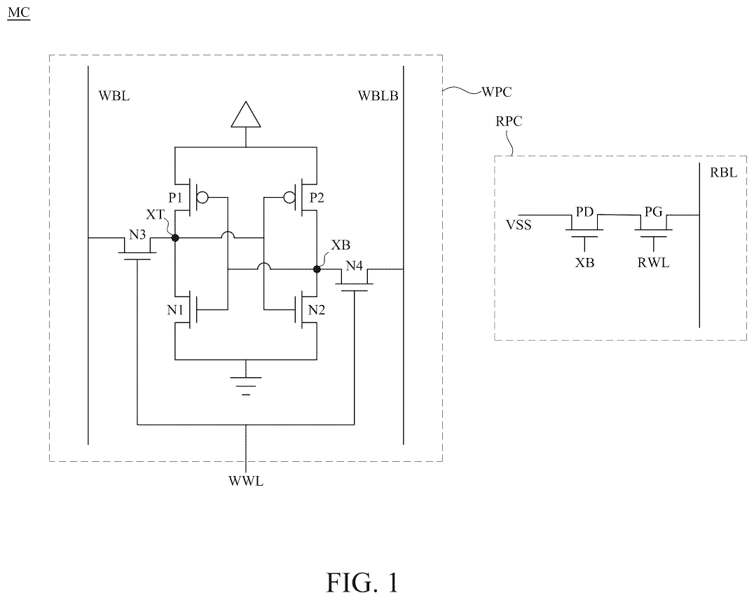

Reference is now made to FIG. 1. FIG. 1 is a schematic diagram of a memory cell MC in accordance with various embodiments of the present disclosure. In some embodiments, the memory cell MC is referred to as a two-port cell. As shown in FIG. 1, the memory cell MC includes a write port circuit WPC and a read port circuit RPC. The write port circuit WPC is coupled to a complimentary pair of write data lines WBL and WBLB. In some embodiments, the write data lines WBL and WBLB transmit signals with bit data, and are referred to as write bit lines. The read port circuit RPC is coupled to a read data line RBL which is referred to as a read bit line. In some embodiments, the memory cell MC is implemented as an 8T static random access memory (SRAM.)

The write port circuit WPC includes p-type transistors P1-P4 and n-type transistors N1-N4. The write port circuit WPC includes a first inverter formed by the transistors P1 and N1 and a second inverter formed by the transistors P2 and N2. The first and second inverters are cross-coupled as a data storage.

For illustration, the drains of the transistors P1 and N1 are electrically connected together, forming a storage node XT. The gates of the transistors P1 and N1 are electrically connected together. The source of the transistor P1 is electrically connected to a supply voltage (i.e., a power line) VDD. The source of the transistor N1 is electrically connected to a complimentary power line VSS (i.e., a supply voltage, or a ground.)

The drains of the transistors P2 and N2 are electrically connected together, forming a storage node XB (also referred to as a storage node bar XB). The gates of the transistors P2 and N2 are electrically connected together. The source of the transistor P2 is electrically connected to the supply voltage VDD. The source of the transistor N2 is electrically connected to the supply voltage VSS.

Furthermore, the storage node XT is electrically connected to the gates of the transistor P2 and N2, and the storage node XB is electrically connected to the gates of the transistors P1 and N1. Therefore, the first and second inverters are cross-coupled as illustrated in FIG. 1.

In some embodiments, the write port circuit WPC further includes a pass-gate device formed with an n-type transistor N3 and another pass-gate device formed with an n-type transistor N4. The source of the transistor N1 is electrically connected to the storage node XT, and the source of the transistor N4 is electrically connected to the storage node XB, forming a write port for data access. Furthermore, the drain of the transistor N3 is electrically connected to the write bit line WBL, and the gate of the transistor N3 is electrically connected to a write word line WWL. Similarly, the drain of the transistor N4 is electrically connected to the write bit line WBLB, and the gate of the transistor N4 is electrically connected to the write word line WWL.

For illustration, the read port circuit RPC of the two-port cell MC includes n-type transistors PD and PG. The transistor PD is also referred to as a read pull-down transistor (RPD,) and the transistor PG is also referred to as a read pass-gate transistor (RPG.) The transistors PD and PG are serially coupled between the support voltage VSS and the read bit line RBL. In the example of FIG. 1, the transistor PD has a source coupled to the supply voltage VSS, and a drain coupled to a drain of the transistor PG. The gate of the transistor PD is coupled to the storage node XB. The source of the transistor PG is coupled to the read bit line RBL, and the gate of the transistor PG is controlled by a read word line RWL.

In some embodiments, in a write operation, the voltage on the write word line WWL is raised above a predetermined level to turn on the transistors N3 and N4. During the write operation, the voltage of the read word line RWL is below a predetermined level, and the transistor PG is turned off. In some examples, the write bit line WBL is pulled high, and the complementary write bit line WBLB is pulled low, or vice versa, in order to write logic “1” or “0” to the memory cell MC.

In some embodiments, in a read operation, the voltage on the read word line RWL is raised to a predetermined level to turn on the transistor PG. During the read operation, the voltage on the write word line WWL is below a predetermined level and the transistors N3-N4 are turned off. The sensing current on the read bit line RBL is then detected by a sense amplifier to determine the logic state of the memory cell MC.

The configurations of FIG. 1 are given for illustrative purposes. Various implements are within the contemplated scope of the present disclosure. For example, in some embodiments, the memory cell MC includes additional devices such as additional pull-down devices and pass-gate devices. In various embodiments, each of the first and second inverters includes one or more pull-down devices configured in parallel.

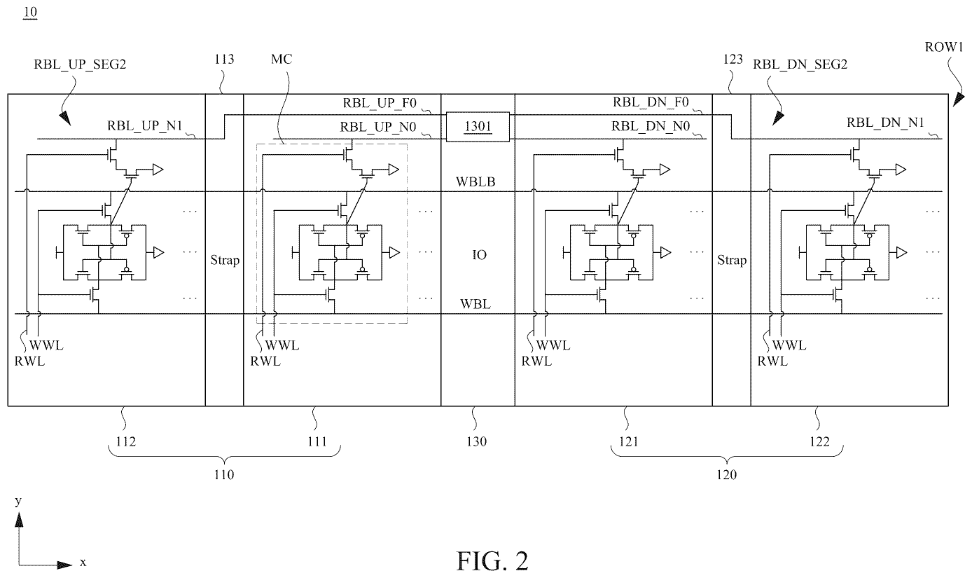

Reference is now made to FIG. 2. FIG. 2 is a schematic diagram of a memory device 10 including the memory cells MC corresponding to FIG. 1, in accordance with other embodiments of the present disclosure.

As shown in FIG. 2, the memory device 10 includes two banks 110 and 120 and an input and output (I/O) circuit 130. The input and output circuit 130 is interposed between the memory banks 110 and 120. With respect to the embodiments of FIG. 1, like elements in FIG. 2 are designated with the same reference numbers for ease of understanding. The specific operations of similar elements, which are already discussed in detail in above paragraphs, are omitted herein for the sake of brevity.

The input and output circuit 130 is crucial component in the memory device 10, acting as the pathways for data to flow in and out. It allows the memory cells to receive data from the external system (input circuits) and sends stored data back out (output circuits).

The memory bank 110 includes multiple memory segments, for example, 111 and 112, and a strap cell 113 interposed between the memory segments 111 and 112. In some embodiments, each of the memory segments 111 and 112 includes several memory cells MC arranged in intersections of columns (along y direction) and rows (along x direction.) Similarly, the memory bank 120 includes multiple memory segments, for example, 121 and 122, and a strap cell 123 interposed between the memory segments 121 and 122. The configurations of the memory segments 121 and 122 are similar to the memory segments 111 and 112. Hence, the repetitious descriptions are omitted here. For the sake of simplicity, only memory cells MC in a row ROW1 and in a column is shown for explanation.

In some embodiments, the strap cells 113 and 123 includes dummy cells. For example, the configurations of the dummy cells are similar to that of the memory cell MC and do not functionally activate during the operations of the memory device 10. In some embodiments, a width of the strap cells 113 and 123 along x direction is about double the width of the memory cell MC.

In some embodiments, the memory cells MC in the same column are coupled to the same pair of the write word line WWL and the read word line RWL.

The memory cells MC in the same row and in the same memory bank are coupled to the same complimentary pair of write data lines WBL and WBLB. For instance, the memory cells MC in the banks 110 are coupled to the write data lines WBL and WBLB.

In some embodiments, the write data line WBL is divided into two portions, in which the first portion is coupled to the memory cells MC in the memory bank 110 and the second portion is coupled to the memory cells MC in the memory bank 120. Similarly, the write data line WBLB is divided into two portions, in which the first portion is coupled to the memory cells MC in the memory bank 110 and the second portion is coupled to the memory cells MC in the memory bank 120.

For illustration, the pair of the write data lines WBL and the WBLB extend along x direction to pass and couple to both of the memory segments in a memory bank. For example, the write data lines WBL and WBLB are coupled to the memory segments 111 and 112 in the memory bank 110.

In some embodiments, the input and output circuit 130 includes a selection circuit (not shown) configured to select, according to the address information of an accessed memory cell MC to be written data, one of the first portions of the write data lines WBL and WBLB and one of the second portions of the write data lines WBL and WBLB. For example, during an operation of writing a data into the memory cell MC in the memory bank 110, the selection circuit charges/discharges the first portions of write data lines WBL and WBLB coupled to the memory bank 110 according to the data while keeping the voltages of the second portions of write data lines WBL and WBLB coupled to the memory bank 120.

In some embodiments, the memory device 10 utilizes read data lines of single conductive line to couple the input and output circuit 130 to memory segments that are arranged closest the input and output circuit 130; on the other hand, the memory device 10 utilizes read data lines having multiple divided portions to couple the input and output circuit 130 to memory segments that are farther to the input and output circuit 130 than the closest memory segments.

For example, with continued reference to FIG. 2, the memory device 10 includes a read data line RBL_UP_N0 coupled to the memory segment 111 and a read data line RBL_UP_SEG2 that is coupled to the memory segment 112 and passes the strap cell 113.

Specifically, the read data line RBL_UP_SEG2 includes two portions-a read data line RBL_UP_N1 and a read data line RBL_UP_F0. In some embodiments, the read data line RBL_UP_F0 passes through the memory segment 111 and the read data line RBL_UP_N1 passes the memory segment 112. As shown in FIG. 2, the read data line RBL_UP_F0 is coupled to the read data line RBL_UP_N1 at the strap cell 113. The read data line RBL_UP_F0 also terminates at the strap cell 113.

Similarly, the memory device 10 also includes a read data line RBL_DN_N0 coupled to the memory segment 121 and a read data line RBL_DN_SEG2 that is coupled to the memory segment 122. Specifically, the read data line RBL_DN_SEG2 includes two portions—a read data line RBL_DN_N1 and a read data line RBL_DN_F0. In some embodiments, the read data line RBL_DN_F0 passes through the memory segment 121 and the read data line RBL_DN_N1 passes the memory segment 122. As shown in FIG. 2, the read data line RBL_DN_F0 is coupled to the read data line RBL_DN_N1 at the strap cell 123. The read data line RBL_DN_F0 also terminates at the strap cell 123.

In some embodiments, the read data lines RBL_UP_N0, RBL_UP_N1, RBL_DN_N0, RBL_DN_N1 are conductive lines made in a first metal layer (e.g., “metal-zero” layer, M0), and the read data line RBL_UP_F0 and RBL_DN_F0 are conductive lines made in a second metal layer (e.g., “metal-two” layer, M2) different from the first metal layer. In some embodiments, the second metal layer is a higher layer than the first metal layer. In some embodiments, conductive lines in the first metal layer has a smaller thickness and/or width along y direction than those of the conductive lines in the second metal layer. Alternatively stated, for the same length (along x direction) of one in the read data lines RBL_UP_N0, RBL_UP_N1, RBL_DN_N0, RBL_DN_N1 and one in the read data line RBL_UP_F0 and RBL_DN_F0, one in the read data line RBL_UP_F0 and RBL_DN_F0 has less resistance, which reduces data transmission loading.

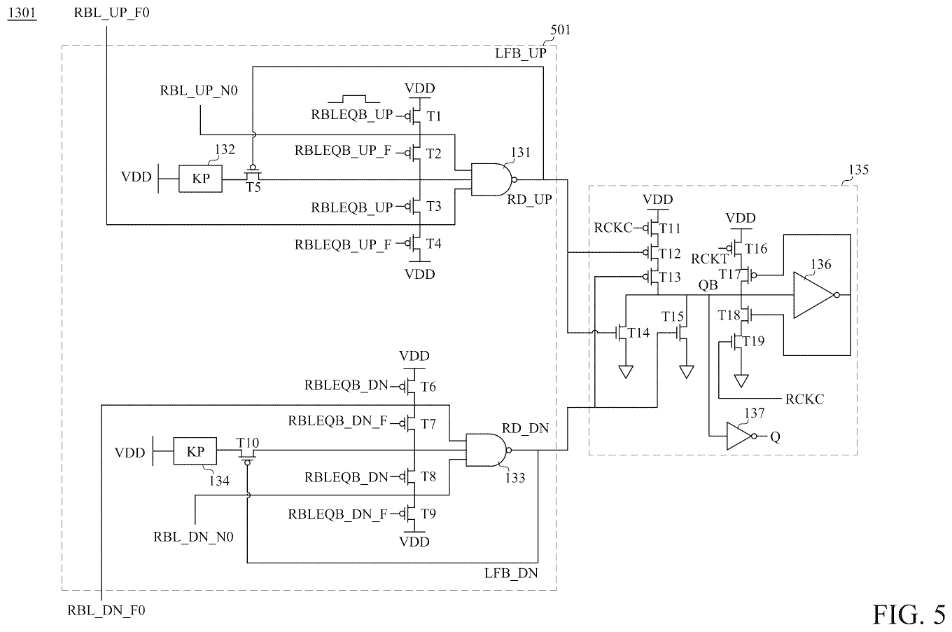

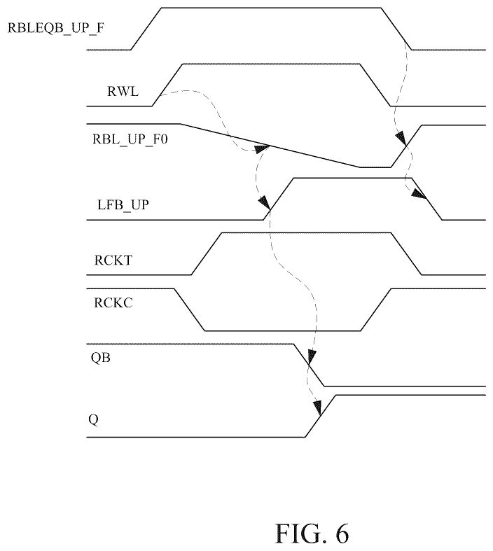

In some embodiments, the input and output circuit 130 includes read circuits (for example, 1301) to read data stored in the memory cells MC. In some embodiments, the memory cells MC in the same row are coupled to a corresponding one in the read circuits. For example, in the embodiments of FIG. 2, the memory cells MC in the memory bank 110 in the row ROW1 are coupled to the read circuit 1301 through the read data lines RBL_UP_N0, RBL_UP_N1, and RBL_UP_F0, Likewise, the memory cells MC in the memory bank 120 in the row ROW1 are coupled to the read circuit 1301 through the read data lines RBL_DN_N0, RBL_DN_N1, and RBL_DN_F0. Specific operational configurations in read operation of the memory device 10 will be discussed with reference to FIGS. 5 and 6.

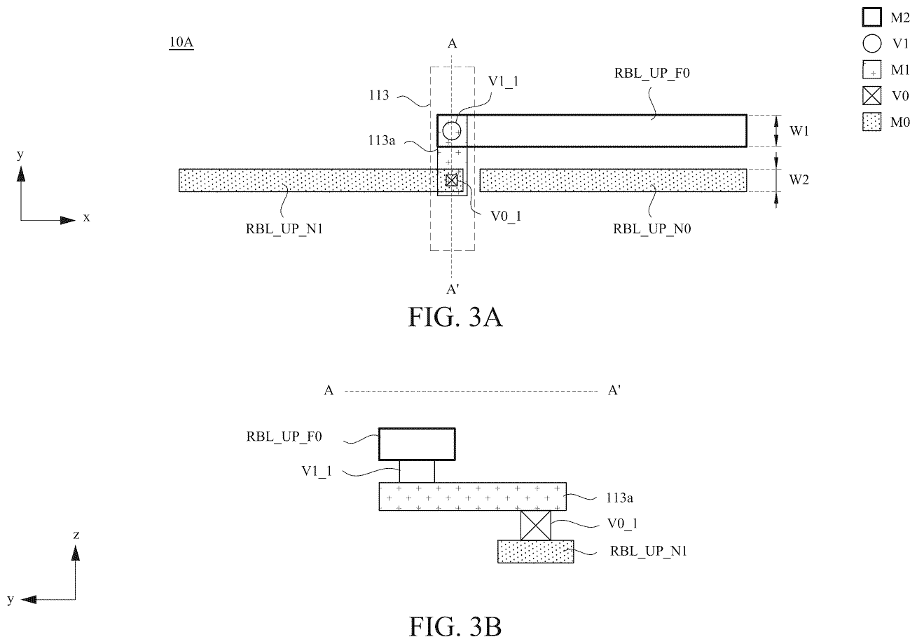

Reference is now made to FIG. 3A. FIG. 3A is a layout diagram 10A of part of the memory device 10 in FIG. 2, in accordance with other embodiments of the present disclosure.

In some embodiments of FIG. 3A, the read data lines RBL_UP_N0, RBL_UP_N1, and RBL_UP_F0 extend in x direction. The read data line RBL_UP_F0 is separated from the read data lines RBL_UP_N0 and RBL_UP_N1 in y direction.

A width W1 of the read data line RBL_UP_F0 is different from a width W2 of the read data lines RBL_UP_N0 and RBL_UP_N1. In some embodiments, the width W2 is smaller than the width W1.

The memory device 10 further includes a connection layer 113a formed in the strap cell 113 to couple the read data line RBL_UP_F0 to the read data line RBL_UP_N1. In some embodiments, the connection layer 113a is in a third metal layer (e.g., “metal-one,” M1) interposed between the first metal layer (e.g., M0) and the second metal layer (e.g., M2). As shown in FIG. 3A, the connection layer 113a extends in y direction and overlaps with the read data line RBL_UP_F0 and the read data line RBL_UP_N1.

Reference is now made to FIG. 3A and FIG. 3B, in which FIG. 3A is a cross-sectional diagram of part of the memory device 10 along line AA′ in FIG. 3A, in accordance with other embodiments of the present disclosure.

The read data line RBL_UP_N1 is coupled to the read data line RBL_UP_F0 through a via V0_1 interposed between the connection layer 113a and the read data line RBL_UP_N1, the connection layer 113a, and a via V1_1 interposed between the connection layer 113a and the read data line RBL_UP_F0.

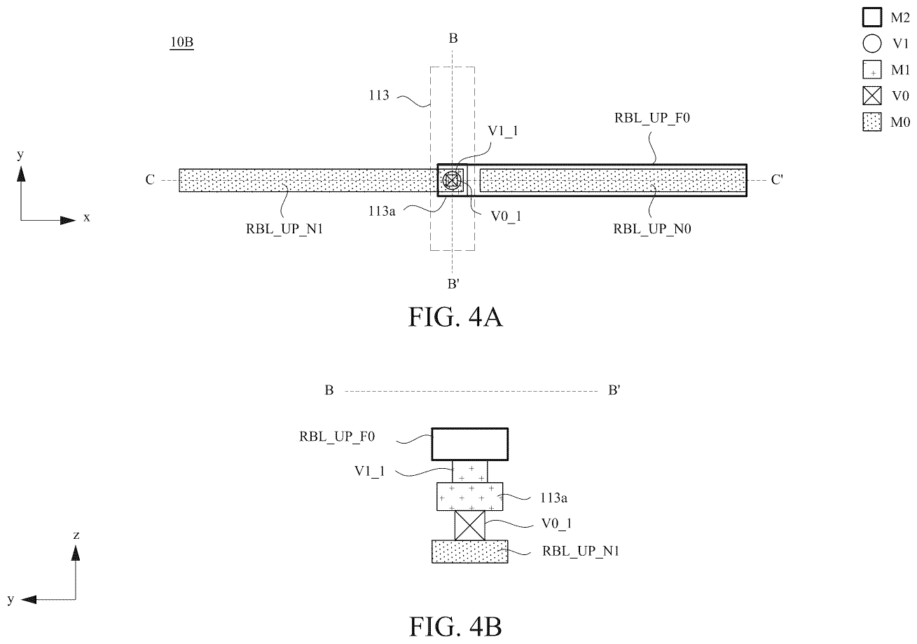

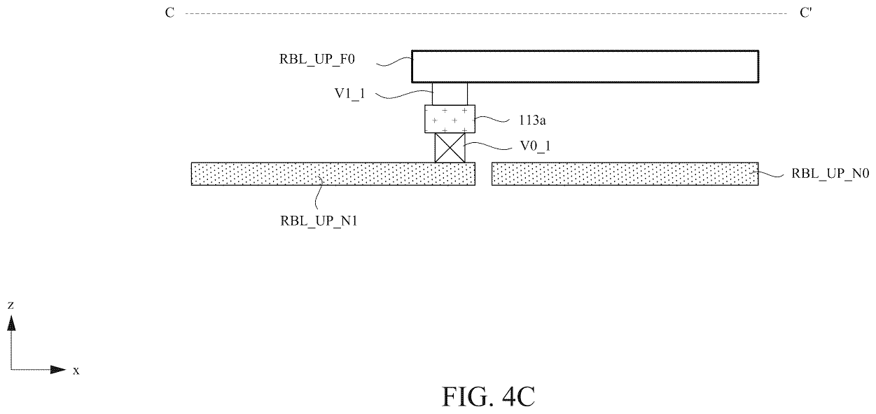

According to different embodiments as shown in FIG. 4A that is a layout diagram 10B of part of the memory device 10 in FIG. 2, the read data line RBL_UP_N0 and the read data line RBL_UP_F0 overlap with each other in the layout view.

FIG. 4B is a cross-sectional diagram of part of the memory device 10 along line BB′ in FIG. 4A, in accordance with other embodiments of the present disclosure. The via V1_1 is right above the via V0_1.

FIG. 4C is a cross-sectional diagram of part of the memory device 10 along line CC′ in FIG. 4A, in accordance with other embodiments of the present disclosure. The read data line RBL_UP_F0 is arranged above the read data lines RBL_UP_N0 and RBL_UP_N1. The read data line RBL_UP_N0 is separated from the read data line RBL_UP_N1 along x direction.

The configurations of the read data lines RBL_DN_F0 and the read data lines RBL_DN_N0 and RBL_DN_N1 are similar to those of the read data lines RBL_UP_F0 and the read data lines RBL_UP_N0 and RBL_UP_N1 illustrated through FIGS. 3A to 4B. Hence, the repetitious descriptions are omitted here.

The configurations of FIGS. 1 to 4C are given for illustrative purposes. Various implements are within the contemplated scope of the present disclosure.

Reference is now made to FIG. 5. FIG. 5 is a schematic circuit diagram of the read circuit 1301, in accordance with other embodiments of the present disclosure.

The read circuit 1301 includes a selection circuit 501 that are coupled to the read data lines RBL_UP_N0, RBL_UP_F0, RBL_DN_N0, and RBL_DN_F0. As shown in FIG. 5, the first part of the selection circuit 501 is coupled to the read data line RBL_UP_N0 and the read data line RBL_UP_F0, and the second part of the selection circuit 501 is coupled to the read data line RBL_DN_N0 and the read data line RBL_DN_F0.

The first part of the selection circuit 501 includes transistors T1-T4 that are coupled in series between voltage terminals providing a voltage V1. In some embodiments, the voltage V1 is a typical supply voltage VDD in the memory device 10. The transistors T1 and T3 are configured to operate in response to a signal RBLEQB_UP. The transistors T2 and T4 are configured to operate in response to a signal RBLEQB_UP_F.

The selection circuit 501 also includes a logic gate (e.g., NAND gate) 131, a keeper circuit 132 and a transistor T5. The keeper circuit 132 and the transistor T5 are coupled in series between the voltage terminal V1 and an input of the logic gate 131. The gate terminal of the transistor T5 is coupled to an output of the logic gate 131.

The read data line RBL_UP_N0 is coupled to an input of the logic gate 131 and a node between the transistors T1 and T2. The read data line RBL_UP_F0 is coupled to an input of the logic gate 131 and a node between the transistors T3 and T4.

Similarly, the second part of the selection circuit 501 includes transistors T6-T9 that are coupled in series between voltage terminals providing the voltages V1 and V2. The transistors T6 and T9 are configured to operate in response to a signal RBLEQB_DN. The transistors T7 and T8 are configured to operate in response to a signal RBLEQB_DN_F.

The selection circuit 501 also includes a logic gate (e.g., NAND gate) 133, a keeper circuit 134 and a transistor T10. The keeper circuit 134 and the transistor T10 are coupled in series between the voltage terminal V1 and an input of the logic gate 133. The gate terminal of the transistor T10 is coupled to an output of the logic gate 133.

The read data line RBL_DN_N0 is coupled to an input of the logic gate 133 and a node between the transistors T8 and T9. The read data line RBL_DN_F0 is coupled to an input of the logic gate 133 and a node between the transistors T6 and T7.

The read circuit 1301 further includes a latch circuit 135 coupled to the outputs of the logic gates 131 and 133. As shown in FIG. 5, the latch circuit 135 includes transistors T11-T19 and inverters 136-137. The transistors T12-T15 configure as a NOR gate. The transistor T11 is coupled in series with the NOR gate and configured to operate in response to a clock signal RCKC. The NOR gate operates in response to outputs of the logic gates 131 and 133. Specifically, the gates of the transistors T12 and T14 receive a signal LFB_UP indicating a read data RD_UP output from the logic gate 131. The gates of the transistors T13 and T15 receive a signal LFB_DN indicating a read data output from the logic gate 133. The inverter 137 is configured to generate an output read data Q in response to an output QB from the NOR gate, in which the logic state of the output read data Q is reversed from the output QB.

The latch circuit 135 further includes P-type transistors T16 and T17 that are coupled to, at the output of the NOR gate, N-type transistors T18 and T19 that are coupled in series. The P-type transistor T16 is configured to operate in response to a clock signal RCKT different from the clock signal RCKC. The N-type transistor T19 is configured to operate in response to the clock signal RCKC. An inverter 136 in the latch circuit 135 is coupled between the output terminal of the NOR gate and gates of the P-type transistor T17 and the N-type transistor T19. Another terminals of the transistors T14, T15, and T19 are coupled to a typical supply voltage VSS, smaller than the supply voltage VDD, in the memory device, for example, a ground potential.

Reference is now made to FIGS. 5 and 6. FIG. 6 is a schematic waveform diagram of signals in the memory device, in accordance with other embodiments of the present disclosure.

In operation, according to some embodiments, the selection circuit 501 is configured to generate the read data RD_UP according to voltages of the read data line RBL_UP_F0 and the read data line RBL_UP_N0 and generate the read data RD_DN according to voltages of the read data line RBL_DN_F0 and the read data line RBL_DN_N0. The latch circuit 135 is configured to generate, in response to the read data RD_UP and RD_DN, the output read data Q corresponding to a data stored in a memory cell MC coupled to a selected one of the RBL_UP_F0, RBL_DN_F0, RBL_UP_N0, and RBL_DN_N0.

For example, with reference to FIG. 5 and FIG. 6, before the read operation performed to a memory cell MC in the memory segment 112 being selected to access, the read data line RBL_UP_F0 is precharged to have a voltage level corresponding to a logic high state in response to at least the RBLEQB_UP_F having a voltage level corresponding to a logic low state.

When the read operation begins, the read word line RWL coupled to the selected memory cell MC (in the memory segment 112) goes high to turn on the read pass-gate transistor PG. In the embodiments of the storage node XB storing the data corresponding to “1” (e.g., high logic state,) the transistor PD is turned on to couple the voltage VSS (e.g., low logic state) to the read data line RBL_UP_N1 and the read data line RBL_UP_F0. Accordingly, the voltage level of the read data line RBL_UP_F0 is pulled down as shown in FIG. 6, and further the logic gate 131 correspondingly generates the signal LFB_UP having the high logic state.

The latch circuit 135 latches the data RD_UP in the signal LFB_UP in response to the clock signal RCKC falling and the clock signal RCKT rising sequentially. Specifically, the output QB goes low and the inverter 137 inverses the output QB to generate the output read data Q having the high logic state, which corresponds to the storage node XB of the selected memory cell MC.

Moreover, after the read operation is finished, the read word line RWL is deactivated. The clock signal RCKC rises to turn off the transistor T11 and turns on the transistor T19. The clock signal RCKT falls to turn on the transistor T16. The transistors T1-T4 are turned on to precharge the read data lines and further to pull down the signal LFB_UP. Alternatively stated, the read circuit 1301 outputs the read data RD_UP having the low logic state to turn off the latch circuit when the read data line RBL_UP_F0 is charged to the high logic state.

The configurations of read operation to memory cells MC coupled to other read data lines in this disclosure are similar to that coupled to the read data line RBL_UP_F0. Hence, the repetitious descriptions are omitted here.

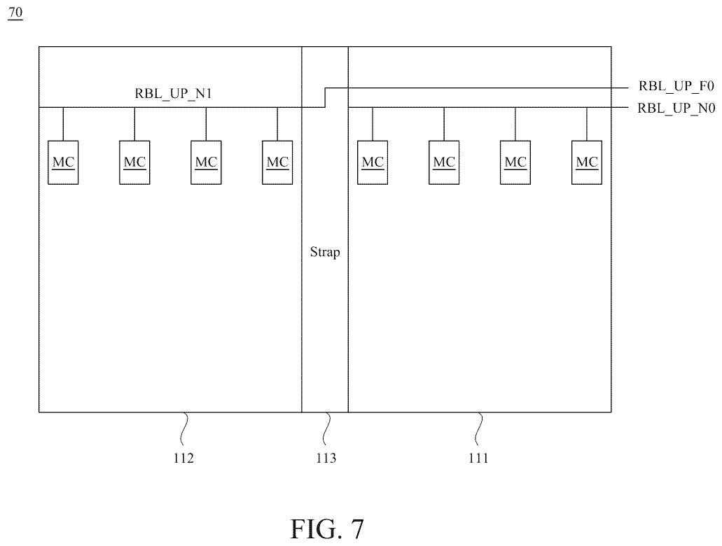

Reference is now made to FIG. 7. FIG. 7 is a schematic diagram of a memory device 70, in accordance with other embodiments of the present disclosure. With respect to the embodiments of FIGS. 1-6, like elements in FIG. 7 are designated with the same reference numbers for ease of understanding. In some embodiments, the memory device 70 is configured with respect to, for example, the memory device 10.

In the embodiments of FIG. 7, the memory segment 111 and the memory segment 112 include same amount of memory cells MC in a row. A number of memory cells MC coupled the read data line RBL_UP_SEG2 composed of the read data line RBL_UP_F0 and the read data line RBL_UP_N1 is consist with a number of memory cells MC coupled the read data line RBL_UP_N0.

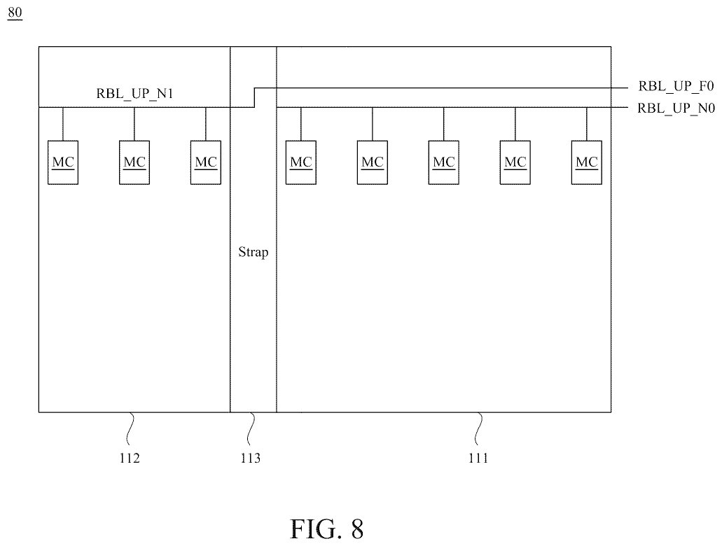

Reference is now made to FIG. 8. FIG. 8 is a schematic diagram of a memory device 80, in accordance with other embodiments of the present disclosure. With respect to the embodiments of FIGS. 1-7, like elements in FIG. 8 are designated with the same reference numbers for ease of understanding. In some embodiments, the memory device 80 is configured with respect to, for example, the memory device 70.

Compared with FIG. 7, the memory segment 111 includes more memory cells MC in a row than the memory segment 112 does. Accordingly, A number of memory cells MC coupled the read data line RBL_UP_SEG2 composed of the read data line RBL_UP_F0 and the read data line RBL_UP_N1 is different from a number of memory cells MC coupled the read data line RBL_UP_N0. In some embodiments, the read data line RBL_UP_SEG2 is coupled to less memory cells MC than the read data line RBL_UP_N0.

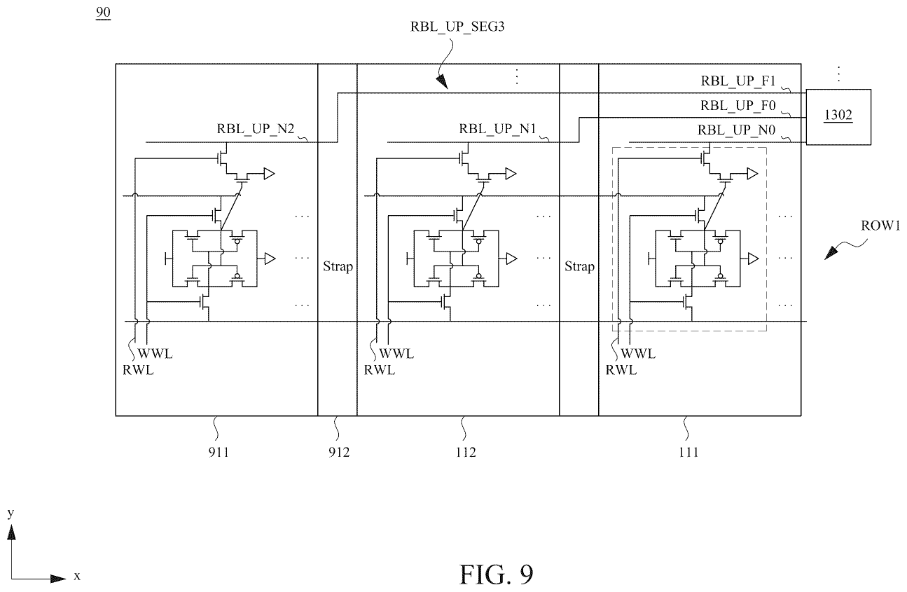

Reference is now made to FIG. 9. FIG. 9 is a schematic diagram of a memory device 90, in accordance with other embodiments of the present disclosure. With respect to the embodiments of FIGS. 1-8, like elements in FIG. 9 are designated with the same reference numbers for ease of understanding. In some embodiments, the memory device 90 is configured with respect to, for example, the memory device 10.

Compared with the memory device 10, the memory device 90 further includes a read data line RBL_UP_SEG3 composed of a read data line RBL_UP_F1 and a read data line RBL_UP_N2. The read data line RBL_UP_SEG3 extends in the x direction to couple to a memory segment 911 in the memory device 90. As shown in FIG. 9, the memory segment 911 is separated from the memory segment 112 by a strap cell 912. Specifically, the read data line RBL_UP_F1 passes through the memory segment 111 and the memory segment 112. The read data line RBL_UP_N2 passes the memory segment 911. The read data line read data line RBL_UP_F1 terminates and coupled to the read data line read data line RBL_UP_N2 at the strap cell 912.

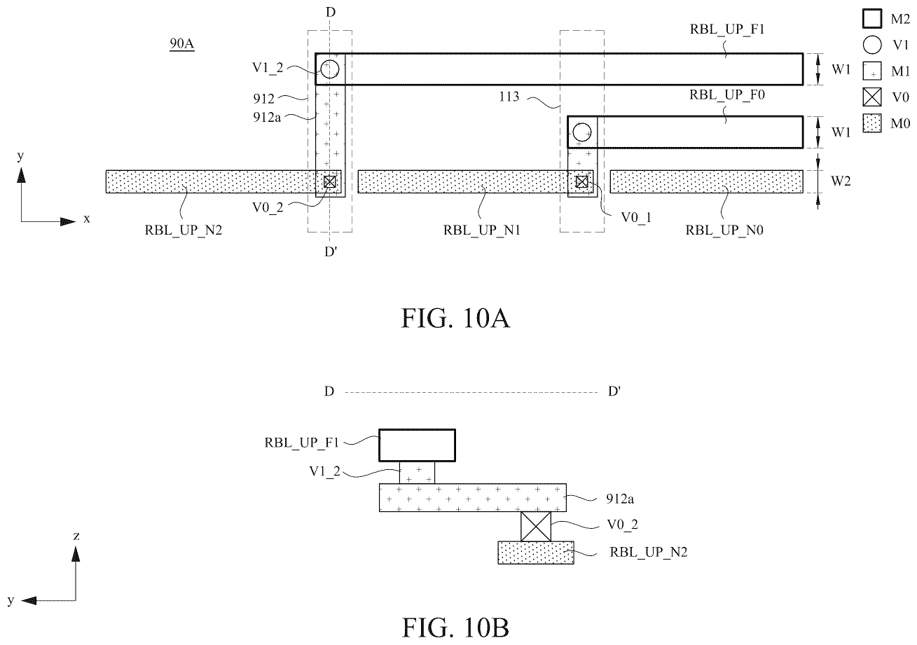

Reference is now made to FIG. 10A to FIG. 10B. FIG. 10A is a layout diagram 90A of part of the memory device 90 in FIG. 9, and FIG. 10B is a cross-sectional diagram of part of the memory device 90 along line DD′ in FIG. 10A, in accordance with other embodiments of the present disclosure.

As shown in FIGS. 10A and 10B, the read data line RBL_UP_F1 is formed in the metal-two layer M2 and extends in x direction to couple to a connection layer 912a formed in the metal-one layer M1 through a via V1_2. The read data line RBL_UP_F1 is separated from the read data line RBL_UP_F0 and the read data lines RBL_UP_N0 to RBL_UP_N2 along y direction. The connection layer 912a is further coupled to the read data line RBL_UP_N2 through a via V0_2.

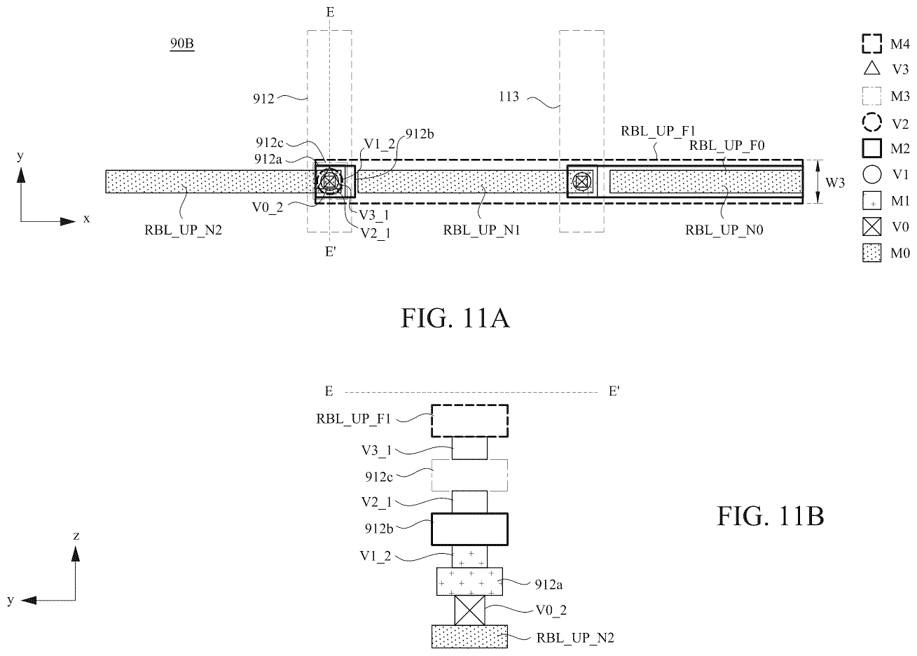

Reference is now made to FIG. 11A to 11B. FIG. 11A is a layout diagram 90B of part of the memory device in FIG. 9, and FIG. 11B is a cross-sectional diagram of part of the memory device 90 along line EE′ in FIG. 11A, in accordance with other embodiments of the present disclosure.

Compared with FIG. 4A, the read data line RBL_UP_F1 is formed in a metal layer (e.g., “metal-four,” M4) above the read data line RBL_UP_F0. In some embodiments, a width W3 of the read data line RBL_UP_F1 is greater than the width W1 of the read data line RBL_UP_F0 along y direction.

As shown in FIG. 11A, the read data line RBL_UP_F1 overlap the read data line RBL_UP_F0 and further read data lines RBL_UP_N0 to RBL_UP_N2 in the layout view.

Specifically, the read data line RBL_UP_F1 is coupled to the read data line RBL_UP_N2 through a via V3_1, a connection layer 912c that is formed in a metal-three layer M3 below the metal-fourth layer M4, a via V2_1, a connection layer 912b that is formed in the metal-two layer M2, a via V1_2, the connection layer 912a, and the via V0_2, as shown in FIGS. 11A to 11B.

In some embodiments of the memory device 90 in FIG. 9, the read data lines RBL_UP_F0, RBL_UP_F1, and RBL_UP_N0 are coupled to a read circuit 1302 for read operation.

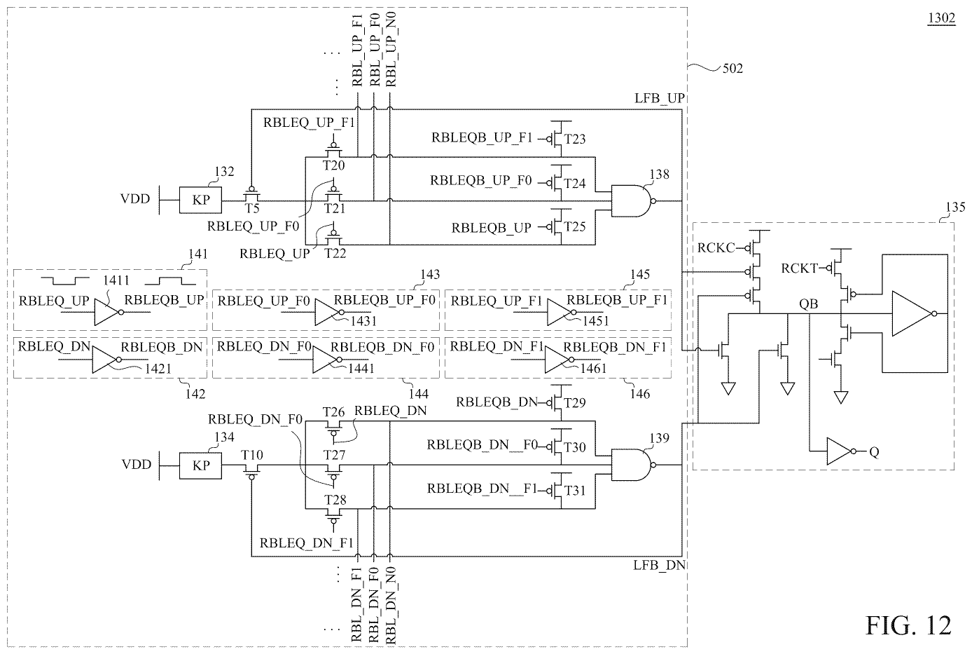

Reference is now made to FIG. 12. FIG. 12 is a schematic circuit diagram of the read circuit 1302 and signal generating circuits 141-146, in accordance with other embodiments of the present disclosure.

As shown in FIG. 12, the read circuit 1302 includes the latch circuit 135 and a selection circuit 502 configured with respect to, for example, the selection circuit 501. The selection circuit 502 is coupled to the read data lines RBL_UP_F0, RBL_UP_F1, and RBL_UP_N0 and the read data lines RBL_DN_F0, RBL_DN_F1, and RBL_DN_N0. The selection circuit 502 includes transistor T5, T10, and P-type T20-T31, the keeper circuits 132, 134, and logic gates (e.g., NAND gates) 138-139.

Specifically, the transistor T20 is coupled between the transistor T5 and a first input of the logic gate 138. The transistor T23 is coupled between the first input of the logic gate 138 and the voltage terminal providing the voltage VDD. The first input of the logic gate 138 is coupled to the read data line RBL_UP_F1. A gate of the transistor T23 receives a signal RBLEQB_UP_F1 generated by an inverter 1451 in the signal generating circuit 145 based on a signal RBLEQ_UP_F1 sent to a gate of the transistor T20.

The transistor T21 is coupled between the transistor T5 and a second input of the logic gate 138. The transistor T24 is coupled between the second input of the logic gate 138 and the voltage terminal providing the voltage VDD. The second input of the logic gate 138 is coupled to the read data line RBL_UP_F0. A gate of the transistor T24 receives a signal RBLEQB_UP_F0 generated by an inverter 1431 in the signal generating circuit 143 based on a signal RBLEQ_UP_F0 sent to a gate of the transistor T21.

The transistor T22 is coupled between the transistor T5 and a third input of the logic gate 138. The transistor T25 is coupled between the third input of the logic gate 138 and the voltage terminal providing the voltage VDD. The third input of the logic gate 138 is coupled to the read data line RBL_UP_N0. A gate of the transistor T25 receives a signal RBLEQB_UP generated by an inverter 1411 in the signal generating circuit 141 based on a signal RBLEQ_UP sent to a gate of the transistor T22.

In some embodiments, the logic gate 138 is further configured to perform an NAND operation to generate the signal LFB_UP according to the voltages at the inputs of the logic gate 138.

Similarly, the transistor T26 is coupled between the transistor T10 and a first input of the logic gate 139. The transistor T29 is coupled between the first input of the logic gate 139 and the voltage terminal providing the voltage VDD. The first input of the logic gate 139 is coupled to the read data line RBL_DN_N0. A gate of the transistor T29 receives a signal RBLEQB_DN generated by an inverter 1421 in the signal generating circuit 142 based on a signal RBLEQ_DN sent to a gate of the transistor T26.

The transistor T27 is coupled between the transistor T10 and a second input of the logic gate 139. The transistor T30 is coupled between the second input of the logic gate 139 and the voltage terminal providing the voltage VDD. The second input of the logic gate 139 is coupled to the read data line RBL_DN_F0. A gate of the transistor T30 receives a signal RBLEQB_DN_F0 generated by an inverter 1441 in the signal generating circuit 144 based on a signal RBLEQ_DN_F0 sent to a gate of the transistor T27.

The transistor T28 is coupled between the transistor T10 and a third input of the logic gate 139. The transistor T31 is coupled between the third input of the logic gate 139 and the voltage terminal providing the voltage VDD. The third input of the logic gate 139 is coupled to the read data line RBL_DN_F1. A gate of the transistor T31 receives a signal RBLEQB_DN_F1 generated by an inverter 1461 in the signal generating circuit 146 based on a signal RBLEQ_DN_F1 sent to a gate of the transistor T28.

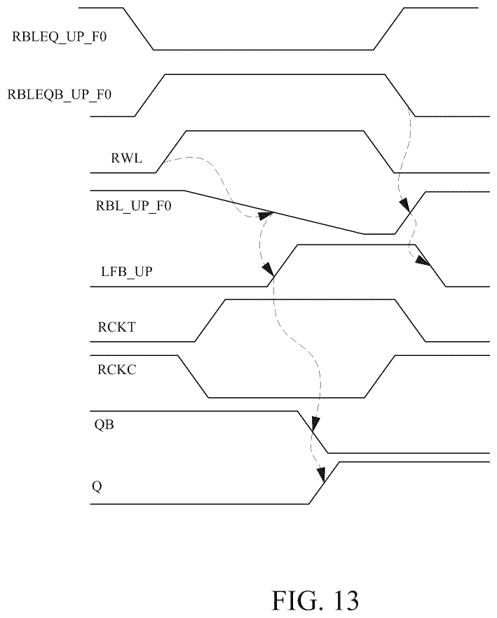

Reference is now made to FIG. 13 for operations of the read circuit 1302. FIG. 13 is a schematic waveform diagram of signals in the memory device 90, in accordance with other embodiments of the present disclosure.

Before the read operation performed to a memory cell MC in the memory segment 112 being selected to access, the read data line RBL_UP_F0 is precharged, according to the voltage VDD to have a voltage level corresponding to the high logic state in response to at least the signal RBLEQB_UP_F0 having a voltage level corresponding to the low logic state and the signal RBLEQ_UP_F0 having a voltage level corresponding to the high logic state.

The configurations of read operation to the memory cell MC in the memory segment 112 of the memory device are similar to those discussed with reference to FIG. 5 to FIG. 6. Hence, the repetitious descriptions are omitted here.

In some embodiments of the read circuits 1301 and 1302, only the selected one read data line is precharged to the voltage VDD, in order to save power consumption in the memory devices 10 and 90.

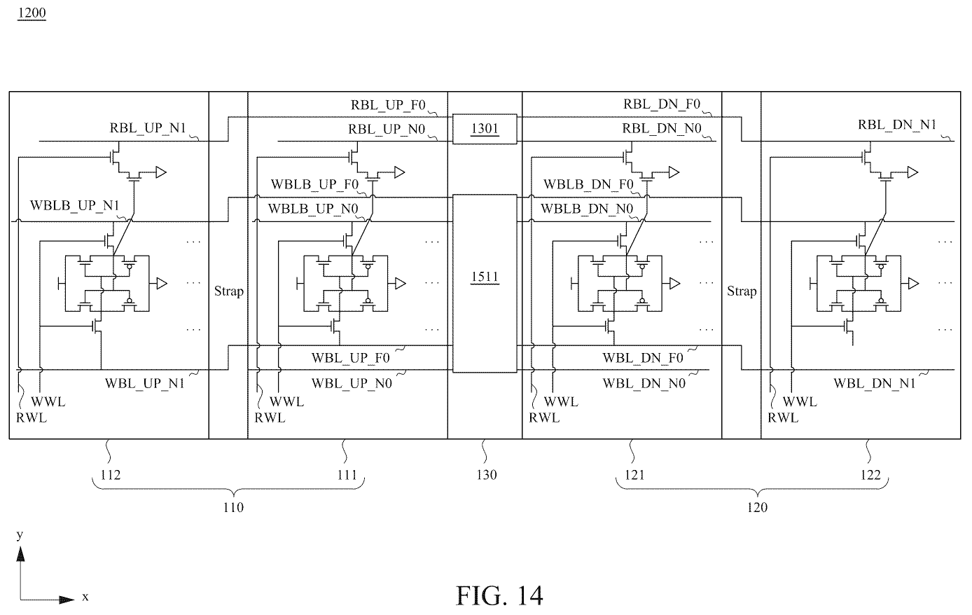

Reference is now made to FIG. 14. FIG. 14 is a schematic diagram of a memory device 1200, in accordance with other embodiments of the present disclosure. With respect to the embodiments of FIGS. 1-13, like elements in FIG. 14 are designated with the same reference numbers for ease of understanding. In some embodiments, the memory device 1200 is configured with respect to, for example, the memory device 10.

Compared with the memory device 10 of FIG. 2, the memory cells MC in different memory segments are coupled to different pairs of write data lines in the memory device. As shown in FIG. 14, the memory cell MC in the memory segment 111 is coupled to a pair of write data lines WBL_UP_N0 and WBLB_UP_N0. The memory cell MC in the memory segment 112 is coupled to another pair of write data lines, for example, a write data line WBL_UP_N0 and a write data line composed of write data lines WBL_UP_F0 and WBL_UP_N1.

In some embodiments, the write data lines WBL_UP_N0, WBL_UP_N1, WBLB_UP_N0, and WBLB_UP_N1 are formed in the metal-zero layer M0 while the write data lines WBL_UP_F0 and WBLB_UP_F0 are formed in the metal-two layer M2. In some embodiments, the write data lines WBL_UP_N0, WBL_UP_N1, WBLB_UP_N0, and WBLB_UP_N1 are configured with respect to, for example, the read data line RBL_UP_N0. The write data lines WBL_UP_F0 and WBLB_UP_F0 are configured with respect to, for example, the read data line RBL_UP_F0.

The configurations of the write data lines in the memory bank 120 are similar to the memory bank 110. Hence, the repetitious descriptions are omitted here.

For illustration, the input and output circuit 130 further includes a write data circuit 1511 coupled the write data lines WBL_UP_N0, WBLB_UP_N0, WBL_UP_F0, WBLB_UP_F0, WBL_DN_N0, WBLB_DN_N0, WBL_DN_F0, and WBLB_DN_F0. In some embodiments, the write data circuit 1511 selectively writes data to one in the pairs of the write data lines.

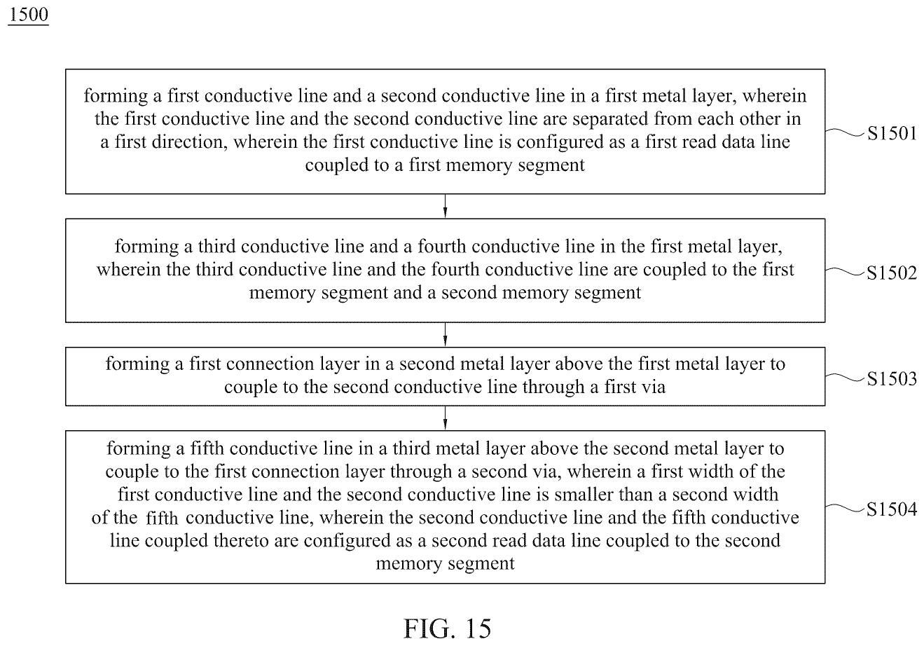

Reference is now made to FIG. 15. FIG. 15 is a flowchart of a method 1500 for operating a memory device to perform a read operation, in accordance with some embodiments of the present disclosure. It is understood that additional operations can be provided before, during, and after the processes shown by FIG. 15, and some of the operations described below can be replaced or eliminated, for additional embodiments of the method. The order of the operations/processes may be interchangeable. Throughout the various views and illustrative embodiments, like reference numbers are used to designate like elements. The method 1500 has operations S1501-S1504 and will be discussed with reference to embodiments of FIG. 1 to FIG. 14.

In operation S1501, The read data line RBL_UP_N0 and the read data line RBL_UP_N1 are formed in the metal layer M0, as shown in FIGS. 3A-3B. The read data line RBL_UP_N0 and the read data line RBL_UP_N1 are separated from each other in x direction.

In operation S1502, as shown in FIG. 2, the write data line WBLB and the write data line WBL are formed in the metal layer M0. The write data line WBLB and the write data line WBL are coupled to both of the memory segment 111 and the memory segment 112.

In operation S1503, the connection layer 113a is formed in the metal layer M1 above the metal layer M0 to couple to the read data line RBL_UP_N1 through the via V0_1.

In operation S1504, the read data line RBL_UP_F0 is formed in the metal layer M2 above the metal layer M1 to couple to the connection layer 113a through the via V1_1.

In some embodiments, the method 1500 further includes operations of forming the read data line RBL_UP_N2 in the metal layer M0 to couple to the memory segment 911 and forming the read data line RBL_UP_F1 in the metal layer M2 to couple to the read data line RBL_UP_N2. A length of the read data line RBL_UP_F1 is greater than a length of the read data line RBL_UP_N2 along x direction, as shown in FIG. 10A.

In some embodiments, as shown in FIG. 11A, the method 1500 further includes operations of forming the connection layer 912a in the metal layer M1, the connection layer 912b in the metal layer M2, the connection layer 912c in the metal layer M3 that are coupled to the read data line RBL_UP_N2 through the via V0_1 and forming the read data line RBL_UP_F1 in the metal layer M4 to couple to the read data line RBL_UP_N2 through the connection layer 912a to the connection layer 912c.

As described above, the memory device in the present disclosure provides divided read bit lines for memory segments arranged away from the input and output circuit, utilizing higher metal layers that serve lower bit line loading in reading operation. It optimizes read operation speed. Compared with other approaches, the access time reduces by around 20% and area reduces by around 10% due to arranging the memory banks on opposite sides of the input and output circuit. Furthermore, the feasibility of read bit lines in this disclosure, such as the number of memory cells coupled to a particular read data line shown in FIG. 8, facilitates balancing loading between the read data lines. Specifically, a total load of the read data line is associated with the length and the number of the memory cells coupled thereto. By reducing the number of memory cells coupled to read data line RBL_UP_SEG2 and forming read data line RBL_UP_F0 in the high metal layer, the load on read data line RBL_UP_N0 and the load on read data line RBL_UP_SEG2 are more balanced, which improves the delay difference in the read data lines. Consequently, the performance of the memory device is enhanced.

In some embodiments, a memory device is disclosed. The memory device includes a first read data line coupled to a first memory segment; a second read data line coupled to a second memory segment, and including a first portion passing through the first memory segment and a second portion passing the second memory segment; and a first strap cell interposed between the first memory segment and the second memory segment. The first portion of the second read data line terminates and coupled to the second portion of the second read data line at the first strap cell.

In some embodiments, the memory device further includes a pair of write data lines extending along a first direction to pass the first memory segment and the second memory segment.

In some embodiments, the first portion of the second read data line and the second portion of the second read data line extend in the first direction and are separated from each other in a second direction different from the first direction.

In some embodiments, the first read data line and the first portion of the second read data line overlap with each other in a layout view.

In some embodiments, the first strap cell includes a plurality of dummy memory cells.

In some embodiments, a first number of memory cells that are the coupled to the first data line is different from a second number of memory cells that are coupled to the second read data line.

In some embodiments, the first number is greater than the second number.

In some embodiments, the memory device further includes a third read data line extending in a first direction to couple to a third memory segment, and including: a first portion passing through the first memory segment and the second memory segment; and a second portion passing the third memory cell; and a second strap cell interposed between the second memory segment and the third memory segment. The first portion of the third read data line terminates and coupled to the second portion of the third read data line at the second strap cell.

In some embodiments, along a second direction different from the first direction, a width of the first portion of the third read data line is greater than the second portion of the third read data line.

In some embodiments, the memory device further includes a third read data line coupled to a third memory segment; and a fourth read data line coupled to a fourth memory segment, wherein a second strap cell is interposed between the third memory segment and the fourth memory segment. The fourth read data line includes a first portion passing the third memory segment and a second portion passing the fourth memory segment. The first portion of the fourth read data line terminates and coupled to the second portion of the fourth read data line at the second strap cell.

In some embodiments, the memory device further includes a read circuit including: a selection circuit coupled to the first read data line to the fourth read data line, and configured to: generate a first read data according to voltages of the first read data line and the second read data line, and generate a second read data according to voltages of the third read data line and the fourth read data line; and a latch circuit configured to generate, in response to the first read data and the second read data, an output read data corresponding to a data stored in a memory cell coupled to a selected one of the first to fourth data lines.

Also disclosed is a memory device that includes a first memory segment coupled to a first read data line; and a second memory segment separated from the first memory segment by a first strap cell, and coupled to a second read data line that passes the first strap cell. The second read data line includes a first portion having a first width and a second portion having a second width smaller than the first width.

In some embodiments, the memory device further includes a pair of write data lines extending along a first direction to couple to the first memory segment and the second memory segment.

In some embodiments, the memory device further includes a third memory segment coupled to a third read data line; a fourth memory segment separated from the third memory segment by a second strap cell, and coupled to a fourth read data line that passes the second strap cell; and a read circuit including: a selection circuit configured to: generate a first read data according to voltages of the first read data line and the second read data line, and generate a second read data according to voltages of the third read data line and the fourth read data line; and a latch circuit configured to generate, in response to the first read data and the second read data, an output read data.

In some embodiments, the latch circuit includes an NOR gate configured to operate in response to the first read data and the second read data; a first inverter configured to generate the output read data in response to an output from the NOR gate; a first P-type transistor coupled in series with the NOR gate and configured to operate in response to a first clock signal; a second P-type transistor and a third P-type transistor coupled to, at an output terminal of the NOR gate, a first N-type transistor and a second N-type transistor that are coupled in series. The second P-type transistor is configured to operate in response to a second clock signal different from the first clock signal, and the second N-type transistor is configured to operate in response to the first clock signal; and a second inverter coupled between the output terminal of the NOR gate and gates of the third P-type transistor and the first N-type transistor.

In some embodiments, the read circuit is configured to output the first read data having a low logic state to turn off the latch circuit when the second read data line is charged to a high logic state.

Also disclosed is a method that includes operations of: forming a first conductive line and a second conductive line in a first metal layer, in which the first conductive line and the second conductive line are separated from each other in a first direction, in which the first conductive line is coupled to a first memory segment and the second conductive line is coupled to a second memory segment; forming a first connection layer in a second metal layer above the first metal layer to couple to the second conductive layer through a first via; forming a third conductive line in a third metal layer above the second metal layer to couple to the first connection layer through a second via, in which a first width of the first conductive line and the second conductive line is smaller than a second width of the third conductive line; and forming a fourth conductive line and a fifth conductive line in the first metal layer, in which the fourth conductive line and the fifth conductive line are coupled to the first memory segment and the second memory segment.

In some embodiments, the first conductive line and the third conductive line are separated from each other in a layout view.

In some embodiments, the method further includes forming a sixth conductive line in the first metal layer to couple to a third memory segment; and forming a seventh conductive line in the third metal layer to couple to the sixth conductive line, in which a length of the seventh conductive line is greater than a length of the third conductive line.

In some embodiments, the method further includes forming a sixth conductive line in the first metal layer to couple to a third memory segment; forming a second connection layer in the second metal layer, a third connection layer in the third metal layer, a fourth connection layer in a fourth metal layer above the third metal layer that are coupled to the second conductive layer through a first via; and forming a seventh conductive line in a fifth metal layer above the fourth metal layer to couple to the sixth conductive line through the second connection layer to the fourth connection layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first read data line coupled to a first memory segment;
a second read data line coupled to a second memory segment, and comprising a first portion passing through the first memory segment and a second portion passing the second memory segment; and
a first strap cell interposed between the first memory segment and the second memory segment,
wherein the first portion of the second read data line terminates and coupled to the second portion of the second read data line at the first strap cell.

2. The memory device of claim 1, further comprising:
a pair of write data lines extending along a first direction to pass the first memory segment and the second memory segment.

3. The memory device of claim 2, wherein the first portion of the second read data line and the second portion of the second read data line extend in the first direction and are separated from each other in a second direction different from the first direction.

4. The memory device of claim 2, wherein the first read data line and the first portion of the second read data line overlap with each other in a layout view.

5. The memory device of claim 1, wherein the first strap cell comprises a plurality of dummy memory cells.

6. The memory device of claim 1, wherein a first number of memory cells that are coupled to the first read data line is different from a second number of memory cells that are coupled to the second read data line.

7. The memory device of claim 6, wherein the first number is greater than the second number.

8. The memory device of claim 1, further comprising:
a third read data line extending in a first direction to couple to a third memory segment, and comprising:
a first portion passing through the first memory segment and the second memory segment; and
a second portion passing the third memory segment; and
a second strap cell interposed between the second memory segment and the third memory segment,
wherein the first portion of the third read data line terminates and coupled to the second portion of the third read data line at the second strap cell.

9. The memory device of claim 8, wherein along a second direction different from the first direction, a width of the first portion of the third read data line is greater than the second portion of the third read data line.

10. The memory device of claim 1, further comprising:
a third read data line coupled to a third memory segment; and
a fourth read data line coupled to a fourth memory segment, wherein a second strap cell is interposed between the third memory segment and the fourth memory segment,
wherein the fourth read data line comprises a first portion passing the third memory segment and a second portion passing the fourth memory segment,
wherein the first portion of the fourth read data line terminates and coupled to the second portion of the fourth read data line at the second strap cell.

11. The memory device of claim 10, further comprising:
a read circuit comprising:
a selection circuit coupled to the first read data line to the fourth read data line, and configured to:
generate a first read data according to voltages of the first read data line and the second read data line, and
generate a second read data according to voltages of the third read data line and the fourth read data line; and
a latch circuit configured to generate, in response to the first read data and the second read data, an output read data corresponding to a data stored in a memory cell coupled to a selected one of the first to fourth read data lines.

12. A memory device, comprising:
a first memory segment coupled to a first read data line; and
a second memory segment separated from the first memory segment by a first strap cell, and coupled to a second read data line that passes the first strap cell,
wherein the second read data line comprises a first portion having a first width and a second portion having a second width smaller than the first width.

13. The memory device of claim 12, further comprising:
a pair of write data lines extending along a first direction to couple to the first memory segment and the second memory segment.

14. The memory device of claim 12, further comprising:
a third memory segment coupled to a third read data line;
a fourth memory segment separated from the third memory segment by a second strap cell, and coupled to a fourth read data line that passes the second strap cell; and
a read circuit comprising:
a selection circuit configured to:
generate a first read data according to voltages of the first read data line and the second read data line, and
generate a second read data according to voltages of the third read data line and the fourth read data line; and
a latch circuit configured to generate, in response to the first read data and the second read data, an output read data.

15. The memory device of claim 14, wherein the latch circuit comprises:
an NOR gate configured to operate in response to the first read data and the second read data;
a first inverter configured to generate the output read data in response to an output from the NOR gate;
a first P-type transistor coupled in series with the NOR gate and configured to operate in response to a first clock signal;
a second P-type transistor and a third P-type transistor coupled to, at an output terminal of the NOR gate, a first N-type transistor and a second N-type transistor that are coupled in series,
wherein the second P-type transistor is configured to operate in response to a second clock signal different from the first clock signal, and
the second N-type transistor is configured to operate in response to the first clock signal; and
a second inverter coupled between the output terminal of the NOR gate and gates of the third P-type transistor and the first N-type transistor.

16. The memory device of claim 14, wherein the read circuit is configured to output the first read data having a low logic state to turn off the latch circuit when the second read data line is charged to a high logic state.

17. A method, comprising:
forming a first conductive line and a second conductive line in a first metal layer, wherein the first conductive line and the second conductive line are separated from each other in a first direction,
wherein the first conductive line is configured as a first read data line coupled to a first memory segment;
forming a third conductive line as a first write data line and a fourth conductive line as a second write data line in the first metal layer;
forming a first connection layer in a second metal layer above the first metal layer to couple to the second conductive line through a first via; and
forming a fifth conductive line in a third metal layer above the second metal layer to couple to the first connection layer through a second via,
wherein the fourth conductive line and the fifth conductive line are coupled to the first memory segment and a second memory segment,
wherein a first width of the first conductive line and the second conductive line is smaller than a second width of the fifth conductive line,
wherein the second conductive line and the fifth conductive line coupled thereto are configured as a second read data line coupled to the second memory segment.

18. The method of claim 17, wherein the first conductive line and the third conductive line are separated from each other in a layout view.

19. The method of claim 17, further comprising:
forming a sixth conductive line in the first metal layer to couple to a third memory segment; and
forming a seventh conductive line in the third metal layer to couple to the sixth conductive line,
wherein a length of the seventh conductive line is greater than a length of the fifth conductive line.

20. The method of claim 17, further comprising:
forming a sixth conductive line in the first metal layer to couple to a third memory segment;
forming a second connection layer in the second metal layer, a third connection layer in the third metal layer, a fourth connection layer in a fourth metal layer above the third metal layer that are coupled to the second connection layer through a first via; and
forming a seventh conductive line in a fifth metal layer above the fourth metal layer to couple to the sixth conductive line through the second connection layer to the fourth connection layer.
